(19) United States
(12) Patent Application Publication
(10) Pub. No.: US 2017/0149004 A1
(43) Pub. Date: May 25, 2017

(54) METHOD FOR MANUFACTURING THIN FILM INCLUDING NICKEL OXIDE NANOPARTICLE AND SOLAR CELL HAVING THE SAME

(71) Applicants: GACHON UNIVERSITY OF INDUSTRY-ACADEMIC COOPERATION FOUNDATION, Seongnam-si (KR); AJOU UNIVERSITY INDUSTRY-ACADEMIC COOPERATION FOUNDATION, Suwon-si (KR)

(72) Inventors: Daeho LEE, Seongnam-si (KR); Hui Joon PARK, Suwon-si (KR); Uisik KWON, Suwon-si (KR)

(73) Assignees: GACHON UNIVERSITY OF INDUSTRY-ACADEMIC COOPERATION FOUNDATION, Seongnam-si (KR); AJOU UNIVERSITY INDUSTRY-ACADEMIC COOPERATION FOUNDATION, Suwon-si (KR)

(21) Appl. No.: 15/355,734

(22) Filed: Nov. 18, 2016

(30) Foreign Application Priority Data
Nov. 20, 2015 (KR) 10-2015-0163283

(51) Int. Cl. H01L 51/42; H01L 51/44

(52) U.S. Cl. CPC H01L 51/422; H01L 51/442; H01L 2251/303; H01L 2251/308; H01L 2031/0344

(57) ABSTRACT

A method of manufacturing a thin film according to an exemplary embodiment of the present invention includes preparing an ink in which nickel oxide nanoparticles are uniformly dispersed, coating the ink on a base layer, and curing the ink to form a thin film including nickel oxide nanoparticles.

### CROSS-REFERENCE TO RELATED APPLICATION

This application claims priority to and the benefit of Korean Patent Application No. 10-2015-0163283 filed in the Korean Intellectual Property Office on Nov. 20, 2015, the entire contents of which are incorporated herein by reference.

### BACKGROUND OF THE INVENTION

(a) Field of the Invention

A method for manufacturing a thin film including nickel oxide nanoparticles and a solar cell using the same are disclosed.

(b) Description of the Related Art

Recently, as energy demands have increased, there has been an increased demand for a solar cell converting sunlight energy into electrical energy. The solar cell is drawing attention as a new power source with a high industrial growth rate every year as a clean energy source for generating electricity from sunlight as an unlimited and nonpolluting energy source.

On the other hand, development of a light and thin flat panel display has been actively undertaken due to recent expansion of the information society, and as an example, an organic light emitting device display needs no separate light source such as a backlight used in a liquid crystal display (LCD) and thus may be thinner and consume less power and also has excellent color reproducibility and thus may realize clearer images.

The solar cell has a basic structure of metal/active layer/metal, but when a heterojunction-type organic semiconductor is used, a hole injection layer or a hole transport layer as a buffer layer may be used between the organic semiconductor and a metal electrode.

The organic light emitting device display includes a pixel electrode, a common electrode, and an organic emission layer between the two electrodes, as well as the hole injection layer or the hole transport layer between the pixel electrode and the organic emission layer.

A widely-used material in a hole injection layer or a hole transport layer of a solar cell or an organic light emitting device display may be PEDOT:PSS (poly(3,4-ethylenedioxythiophene):poly(styrene sulfonate)), spiro-OMeTAD (2,2′,7,7′-tetrakis(N,N′-di-p-methoxyphenylamine)-9,9′-spirobifluorene), a poly-triarylamine derivative, a poly-diketopyrrolopyrrole derivative, and the like, and these materials may prevent direct contact of an active layer with an ITO (indium tin oxide) and may control their interface.

The PEDOT:PSS among these materials contains a large amount of sulfonic acid and thus is acidic, and resultantly, may deteriorate a long-term life or reliability of a device. In addition, corrosion on the interface of the PEDOT:PSS with unstable ITO may be a largest factor in deteriorating overall characteristics of the device. Furthermore, indium that is decomposed through a chemical reaction with the sulfonic acid is diffused into all the layers of the device and thus may deteriorate performance of the device.

### SUMMARY OF THE INVENTION

An exemplary embodiment of the present invention lowers a leakage current of a thin film and thus increases power conversion efficiency of a solar cell.

An exemplary embodiment of the present invention improves anti-corrosion of a thin film and thus durability and reliability.

An exemplary embodiment of the present invention reduces a production cost of a thin film.

An exemplary embodiment of the present invention provides an easy manufacturing process of a thin film.

Embodiments of the present invention may be used for additional purposes that are not specifically described above.

A method for manufacturing a thin film according to an exemplary embodiment of the present invention includes preparing an ink in which nickel oxide nanoparticles are uniformly dispersed, coating the ink on a base layer, and curing the ink to form a thin film including nickel oxide nanoparticles.

Herein, the preparing of the ink includes preparing a precursor solution including a nickel oxide nanoparticle precursor, adding a reducing agent to the precursor solution to produce nickel oxide nanoparticles by reducing the nickel oxide nanoparticle precursor, separating the nickel oxide nanoparticles from the precursor solution, and uniformly dispersing the separated nickel oxide nanoparticles in an organic solvent to prepare an ink.

The nickel oxide nanoparticle precursor may be nickel(II) acetylacetonate (C₁₀H₁₄NiO₄).

The solvent of the precursor solution may be oleylamine (C₁₈H₃₇N).

The reducing agent may be borane-dimethylamine ((CH₃)₂NH.BH₃), borane-triethylamine ((C₂H₅)₃N.BH₃), or borane-trimethylamine ((CH₃)₃N.BH₃). In the separating of the nickel oxide nanoparticles, the nickel oxide nanoparticles may be separated from the precursor solution through centrifugation.

The organic solvent may be tetradecane (C₁₄H₃₀.

In the preparing of the ink, the nickel oxide nanoparticles may be uniformly dispersed in an organic solvent by ultrasonication treatment.

In the forming of the thin film, the ink may be heated at a temperature of about 200° C. to about 500° C. to cure the ink.

A laser may be irradiated to the ink to cure the ink.

In the producing of the nickel oxide nanoparticles, the precursor solution may be heated and stirred at a temperature of about 80° C. to about 200° C. for about 1 hour or more and then the reducing agent may be added.

Between the separating of the nickel oxide nanoparticles and the preparing of the ink, the method may further include washing the nickel oxide nanoparticles with methanol, ethanol, or acetone.

A solar cell according to an exemplary embodiment of the present invention includes a first electrode, a hole transport layer, an active layer, an electron transport layer, and a second electrode that are sequentially stacked on a substrate, wherein the hole transport layer is a thin film where the nickel oxide nanoparticles are uniformly dispersed.

The solar cell may further include a hole injection layer between the first electrode and the hole transport layer, and the hole injection layer may be a thin film where the nickel oxide nanoparticles are uniformly dispersed.

A thickness of the hole transport layer may be in a range of about 10 nm to about 100 nm.

The first electrode may include an ITO, the active layer may include CH₃NH₃PbI₃, the electron transport layer may include PCBM (phenyl-C₆₁-butyric acid methyl ester), and the second electrode may include LiF and Al.

An exemplary embodiment of the present invention may reduce a current leakage of a thin film and thus increase power conversion efficiency of a solar cell, improve anti-corrosion of the thin film and thus enhance durability and reliability, and reduce a manufacture cost of the thin film and thus improve ease of a manufacturing process of the thin film.

### BRIEF DESCRIPTION OF THE DRAWINGS

FIG. 1 is a schematic view showing a solar cell including a thin film according to an embodiment.

FIG. 2 is a band diagram showing an energy level of the solar cell of FIG. 1.

FIG. 3 is a schematic flowchart showing a method for manufacturing a thin film according to an embodiment.

FIG. 4A is a low magnification SEM image showing the surface of a thin film according to an embodiment, and FIG. 4B is a high magnification SEM image showing the surface of the thin film according to an example.

FIG. 5 is a SEM image showing the cross-section of a solar cell including the thin film according to examples as a hole transport layer.

FIG. 6 is a graph comparing voltage characteristics of a conventional hole transport layer for a solar cell and the hole transport layer of examples.

FIG. 7 is a graph comparing current density characteristics of the conventional hole transport layer and the hole transport layer of examples.

FIG. 8 is a graph comparing fill factor characteristics of the conventional hole transport layer and the hole transport layer of examples.

FIG. 9 is a graph comparing power conversion efficiency characteristics of the conventional hole transport layer and the hole transport layer of examples.

FIG. 10 is a graph comparing current density characteristics about a voltage of the conventional hole transport layer and the hole transport layer of examples.

FIG. 11A is a low magnification SEM image showing the surface of the thin film according to an embodiment, and FIG. 11B is a high magnification SEM image showing the surface of the thin film according to an example.

FIG. 12 is a SEM image showing the cross-section of a solar cell including the thin film according to an example as a hole transport layer.

### DETAILED DESCRIPTION

The present invention will be described more fully hereinafter with reference to the accompanying drawings, in which exemplary embodiments of the invention are shown. As those skilled in the art would realize, the described embodiments may be modified in various different ways, all without departing from the spirit or scope of the present invention. In the drawings, parts having no relationship with the description are omitted for clarity of the embodiments, and the same or similar constituent elements are indicated by the same reference numerals throughout the specification. In addition, detailed description of widely known technologies will be omitted.

In the drawings, the thickness of layers, films, panels, regions, etc., are exaggerated for clarity. It will be understood that when an element such as a layer, film, region, or substrate is referred to as being “on” another element, it can be directly on the other element or intervening elements may also be present. When an element is referred to as being “directly on” another element, there are no intervening elements present. In contrast, it will be understood that when an element such as a layer, film, region, or substrate is referred to as being “under” another element, it can be directly under the other element or intervening elements may also be present. Further, when an element is referred to as being “directly under” another element, there are no intervening elements present.

In addition, unless explicitly described to the contrary, the word “comprise” and variations such as “comprises” or “comprising” will be understood to imply the inclusion of stated elements but not the exclusion of any other elements.

In the present disclosure, for better understanding and ease of description, a thin film including the nickel oxide nanoparticles uniformly dispersed therein is applied to a hole transport layer 130 of a solar cell, but the thin film may be applied to an organic light emitting device display as well as the solar cell.

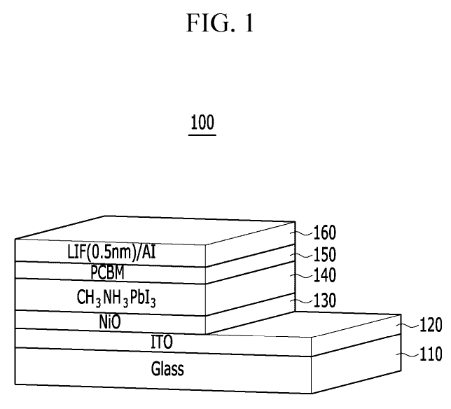

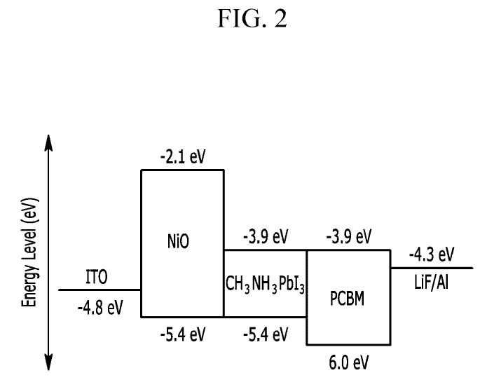

FIG. 1 is a schematic view of a solar cell including a thin film according to an embodiment, and FIG. 2 is a band diagram showing an energy level of the solar cell of FIG. 1.

The solar cell of FIG. 1 and the energy level band diagram of FIG. 2 are figuratively shown for better understanding and ease of description, and thus a solar cell according to exemplary embodiments may have various structures and include more layers than the shown layers, and each layer may have various energy levels.

Referring to FIGS. 1 and 2, a solar cell 100 includes a first electrode 120, a hole transport layer 130, an active layer 140, an electron transport layer 150, and a second electrode 160 that are sequentially stacked on a substrate 110, wherein the hole transport layer 130 is a thin film where the nickel oxide (NiO) nanoparticles are uniformly dispersed.

The solar cell 100 may be, for example, a perovskite solar cell, but is not limited thereto.

The substrate 110 may include, for example, glass, but is not limited thereto, and may include various polymer materials.

The first electrode 120 may also be called a positive electrode or an anode electrode, and may include, for example, ITO (indium tin oxide). The second electrode 160 facing the first electrode 120 may also be called a negative electrode or a cathode electrode, and may include, for example, LiF and Al.

The hole transport layer 130 may be, for example, a thin film where the nickel oxide (NiO) nanoparticles are uniformly dispersed. The hole transport layer 130 may make holes generated in the first electrode 120 be easily injected into the active layer 140.

The thin film according to exemplary embodiments may reduce a leakage current and minimize recombination of carriers generated by light and thus increase efficiency of the solar cell 100, and also reduce corrosion and thus improve durability and reliability of the solar cell 100.

The nickel oxide nanoparticles (NiO NP) included in the hole transport layer 130 may be easily synthesized, may remarkably reduce a manufacturing cost during mass production due to its inexpensive precursor material, and may secure a long shelf life. In addition, the nickel oxide nanoparticles have excellent anti-corrosion with respect to air and equivalents or excellent hole transport capability compared with the PEDOT:PSS, a general hole transport layer material.

A thickness of the hole transport layer 130 may be in a range of about 10 nm to about 100 nm. Within the thickness range, power conversion efficiency of a solar cell including the hole transport layer 130 may be improved. More specifically, the thickness of the hole transport layer 130 may be in a range of about 40 nm to about 45 nm. Within the range, the power conversion efficiency of the solar cell 100 may be much improved compared with that of a conventional solar cell including the PEDOT:PSS as a hole transport layer material.

Although not shown, a solar cell according to exemplary embodiments may further include a hole injection layer between the first electrode 120 and the hole transport layer 130. The hole injection layer may be a thin film where the nickel oxide nanoparticles are uniformly dispersed. This hole injection layer may adjust bandgap energy in order to facilitate movement of holes generated in the first electrode 120 to the hole transport layer 130.

The active layer 140 absorbs light and generates power, and may include, for example, CH₃NH₃PbI₃, but is not limited thereto.

The electron transport layer 150 may include PCBM (phenyl-C₆₁-butyric acid methyl ester), but is not limited thereto, and may include various materials. The electron transport layer 150 may make electrons generated in the second electrode 160 be easily injected into the active layer 140.

Although not shown, in this disclosure, a thin film according to exemplary embodiments may be applied to a hole transport layer or a hole injection layer of an organic light emitting device display.

The organic light emitting device display includes a first electrode, a hole injection layer, a hole transport layer, an organic emission layer, an electron transport layer, an electron injection layer, and the like, and a thin film where the nickel oxide nanoparticles are uniformly dispersed as a hole injection layer or a hole transport layer.

Hereinafter, a method for manufacturing a thin film of the hole transport layer 130 is described in detail.

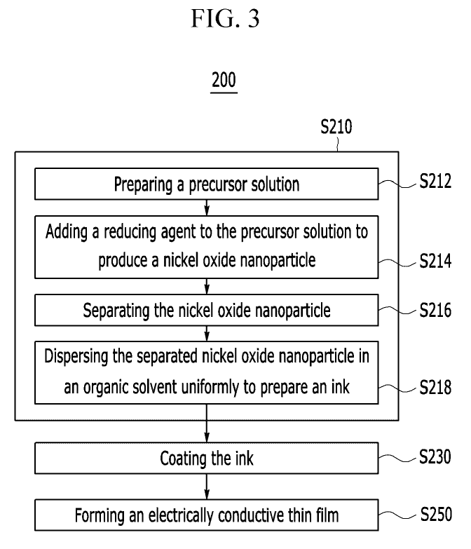

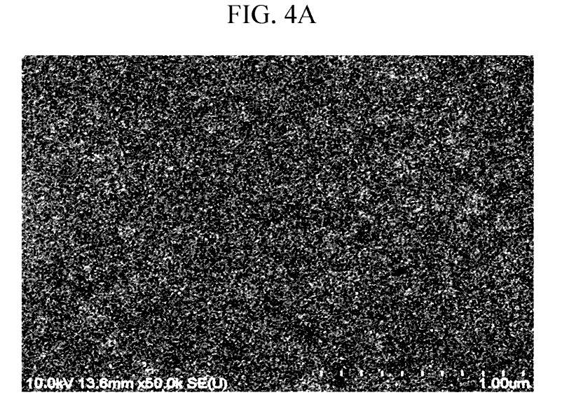

FIG. 3 is a schematic flowchart of a method for manufacturing a thin film according to an embodiment.

Referring to FIG. 3, a method for manufacturing a thin film includes preparing an ink in which nickel oxide (NiO) nanoparticles are uniformly dispersed (S210), coating the ink on a base layer (S230), and curing the ink to form a thin film including the nickel oxide nanoparticles (S250).

Herein, the preparing of the ink (S210) includes preparing a precursor solution including a nickel oxide nanoparticle precursor (S212), adding a reducing agent to the precursor solution to produce nickel oxide nanoparticles by reducing the nickel oxide nanoparticle precursor (S214), separating the nickel oxide nanoparticles from the precursor solution (S216), and dispersing the separated nickel oxide nanoparticles in an organic solvent uniformly to prepare an ink (S218).

The preparing of the ink (S210) will now explained in detail. First, the precursor solution including a nickel oxide nanoparticle precursor (S212) is prepared.

Herein, the nickel oxide nanoparticle precursor may be nickel(II) acetylacetonate (C₁₀H₁₄NiO₄), and the solvent of the precursor solution may be oleylamine (C₁₈H₃₇N). Since the nickel(II) acetylacetonate and oleylamine are inexpensive, a manufacturing cost of oxidized nanoparticle ink may be reduced. In addition, the nickel(II) acetylacetonate may generate the nickel oxide nanoparticles via a reducing agent with excellent efficiency.

The precursor solution may further include oleic acid (C₁₈H₃₄O₂). Regardless of inclusion of the oleic acid, the precursor solution may be used to form the hole transport layer 130 for a solar cell.

Subsequently, a reducing agent is added to the precursor solution to produce the nickel oxide nanoparticles (S214).

For example, the reducing agent may be borane-dimethylamine ((CH₃)₂NH.BH₃), borane-triethylamine ((C₂H₅)₃N.BH₃), or borane-trimethylamine ((CH₃)₃N.BH₃), but is not limited thereto, and may include various materials. By the addition of the reducing agent, the nickel oxide nanoparticle precursor is reduced to nickel oxide nanoparticles.

Herein, the precursor solution may be heated and stirred at about 80° C. to about 200° C. for a predetermined time before adding the reducing agent thereto. For example, the heating may be performed for greater than or equal to about 1 hour. Accordingly, oxygen dissolved in the precursor solution may be removed and moisture may be evaporated therefrom, so that a reduction reaction may be more efficiently performed.

In addition, after performing the reduction reaction by adding the reducing agent to the precursor solution, the precursor solution may be cooled to room temperature.

Subsequently, the nickel oxide nanoparticles are separated from the precursor solution (S216).

The separation of the nickel oxide nanoparticles from the precursor solution may be performed through a centrifugation process. The centrifugation process may be performed at about 1000 rpm to about 10000 rpm for about 15 minutes by using, for example, a centrifuge.

Subsequently, the separated nickel oxide nanoparticles are gathered and then uniformly dispersed in an organic solvent to prepare ink (S218).

Herein, the organic solvent may be tetradecane (C₁₄H₃₀). In general, an ink including a nickel oxide may be prepared by using toluene (C₇H₈), alpha-terpineol (C₁₀H₁₈O), hexane (C₆H₁₄), and the like as the organic solvent, but when the ink is prepared by using tetradecane as the organic solvent, excellent power conversion efficiency of a solar cell may be obtained.

After mixing the separated nickel oxide nanoparticles with the tetradecane solvent, the solution is exposed to ultrasonic waves through ultrasonication to uniformly disperse the nickel oxide nanoparticles in the solvent. Accordingly, when the ink including the nickel oxide nanoparticles is coated on a base layer, uniform performance in the entire region may be obtained. For example, when the ink is cured and thus functions as the hole transport layer 130 for a solar cell, uniform hole transport capability in the entire region may be obtained.

Further, the nickel oxide nanoparticles may be additionally washed with methanol, ethanol, or acetone between the separation of the nickel oxide nanoparticles (S216) and the preparation of the ink (S218). Accordingly, the nickel oxide nanoparticles may have more purity for dispersion in the tetradecane and thus improve performance of a thin film.

The ink including the nickel oxide nanoparticles according to exemplary embodiments may be easily synthesized, may be manufactured with a low cost since its precursor material, nickel(II) acetylacetonate (C₁₀H₁₄NiO₄), is inexpensive, and may have high stability with respect to air. In addition, storage life of the ink may be improved.

Subsequently, the prepared ink is coated on a base layer (S230).

Herein, the base layer may be, for example, the first electrode 120 of a solar cell. In addition, the ink including the uniformly-dispersed nickel oxide nanoparticles may be coated on ITO of a solar cell. However, the base layer is not limited thereto, and may be an anode for an organic light emitting device display, or may have various other device configurations.

The ink may be coated by one of spin coating, dip coating, inkjet printing, screen printing, gravure printing, offset printing, micro-imprinting, and nano-imprinting processes.

These solution processes may be remarkably inexpensive compared with chemical vapor deposition (CVD), physical vapor deposition (PVD), or the like, and are quick. In addition, the concentration of the ink may be easily controlled to adjust thickness of a thin film as needed.

Next, the ink is cured to form a thin film including nickel oxide nanoparticles (S250).

The ink coated on the base layer may be heated and cured at about 200° C. to about 500° C.

A general method of manufacturing a thin film includes deposition of nickel oxide nanoparticles through the CVD or PVD process and then performing heat treatment at greater than or equal to about 500° C., but the method of manufacturing a thin film according to exemplary embodiments may reduce cost and time for a reaction process, since the ink may be cured at less than or equal to 500° C.

Alternatively, the ink coated on the base layer may be cured by irradiating a laser. In this case, a predetermined pattern may be formed on the thin film as necessary.

The thin film manufactured by the manufacturing method may be applied to a hole transport layer 130 of a solar cell or a hole transport layer of an organic light emitting device display.

Hereinafter, the present invention is illustrated in more detail with reference to examples, but these examples are not in any sense to be interpreted as limiting the scope of the invention.

### Example 1

A precursor solution is prepared by mixing 1 mmol of nickel(II) acetylacetonate (C₁₀H₁₄NiO₄) as a nickel oxide nanoparticle precursor with 15 ml of oleylamine (C₁₈H₃₇N).

Subsequently, the solution is heated at about 110° C. for about one hour while being stirred to release a gas such as oxygen and the like dissolved therein and evaporate moisture.

Then, the precursor solution is cooled to about 90° C., and a mixture of about 2.4 mmol of borane-triethylamine ((C₂H₅)₃N.BH₃) as a reducing agent with about 2 ml of oleylamine (C₁₈H₃₇N) is injected into the precursor solution. The obtained mixture is stirred at about 90° C. for about 1 hour to reduce the nickel oxide nanoparticle precursor into nickel oxide nanoparticles. Then, the solution is cooled to room temperature.

Subsequently, about 30 ml of ethanol (C₂H₆O) is added to the precursor solution, and the mixture is centrifuged at about 3000 to 4000 rpm for 15 minutes with a centrifuge to separate the nickel oxide nanoparticles. The separated nickel oxide nanoparticles are cleaned in ethanol 2 to 3 times.

The separated nickel oxide nanoparticles are mixed with tetradecane (C₁₄H₃₀) as an organic solvent and uniformly dispersed therein through ultrasonication to prepare an ink in which the nickel oxide (NiO) nanoparticles are uniformly dispersed.

Subsequently, the ink is spin-coated at about 500 to 5000 rpm for about 1 minute on a base layer formed of ITO (indium tin oxide) uniformly coated on an organic substrate.

Then, the ink is cured through a heat treatment at greater than or equal to about 200° C. to form a thin film.

### Example 2

A thin film is formed according to the same method as Example 1, except for mixing 1 mmol of nickel(II) acetylacetonate (C₁₀H₁₄NiO₄) as a nickel oxide nanoparticle precursor with 15 ml of oleylamine (C₁₈H₃₇N) and additionally adding about 1 mmol of oleic acid (C₁₈H₃₄O₂) thereto.

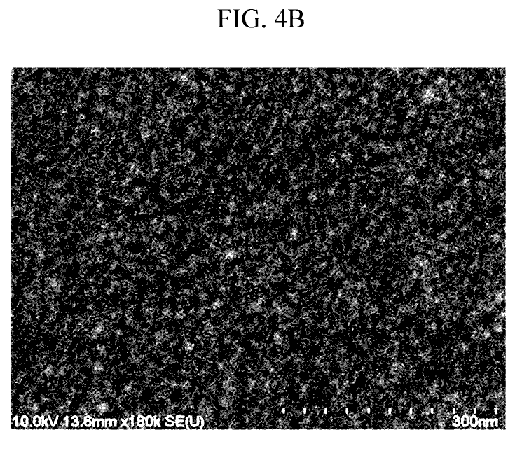

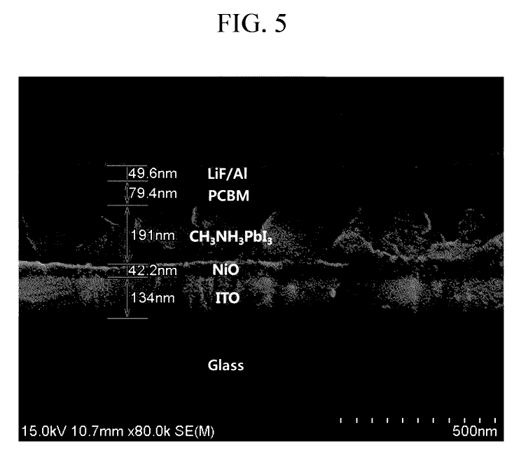

FIG. 4A is a low magnification SEM image showing the surface of the thin film according to Example 1, and FIG. 4B is a high magnification SEM image showing the surface of the thin film according to Example 1. FIG. 5 is a SEM image showing the cross-section of a solar cell including the thin film of Example 1 as a hole transport layer.

The solar cell 100 shown in FIG. 5 may have a structure in which a substrate 110 including glass, a first electrode 120 including ITO, a hole transport layer 130, the thin film according to Example 1, an active layer 140 including CH₃NH₃PbI₃, an electron transport layer 150 including PCBM (phenyl-C₆₁-butyric acid methyl ester), and a second electrode including LiF and Al are sequentially stacked. In FIG. 5, the hole transport layer 130 has a thickness of 41.9 nm, but may have various thicknesses by controlling the concentration of the ink.

When a solar cell has a hole transport layer including PEDOT:PSS, an open circuit voltage (Voc), a current density (Jsc), a fill factor (FF), and power conversion efficiency (PCE) of the solar cell in each case in which the hole transport layer 130 according to Example 1 has a thickness of about 25 nm to about 30 nm, about 40 nm to about 45 nm, and about 60 nm to about 65 nm are shown in Table 1.

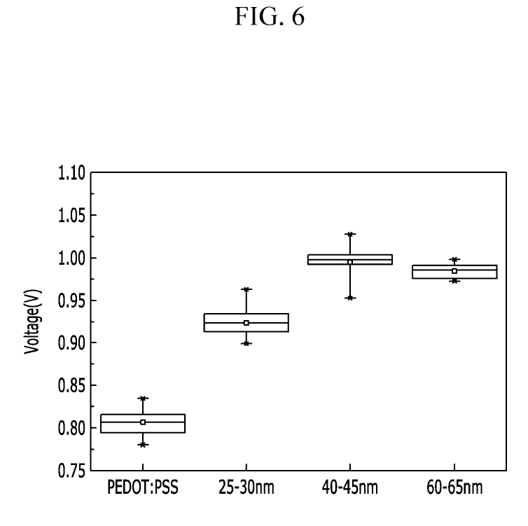

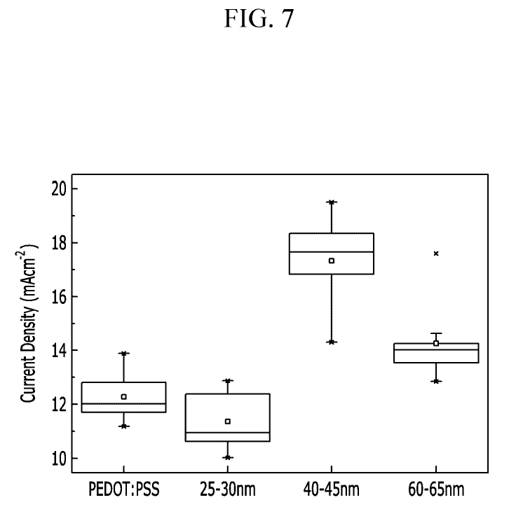

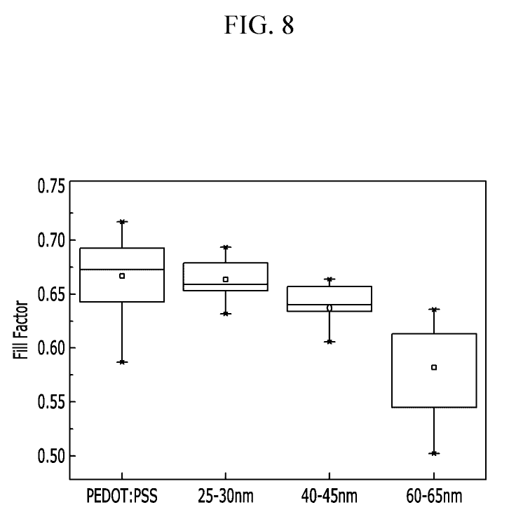

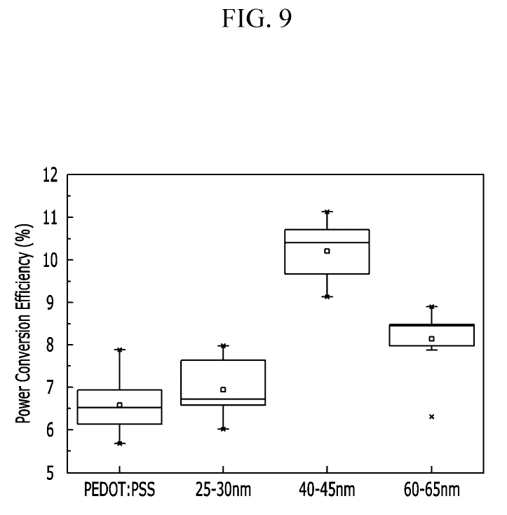

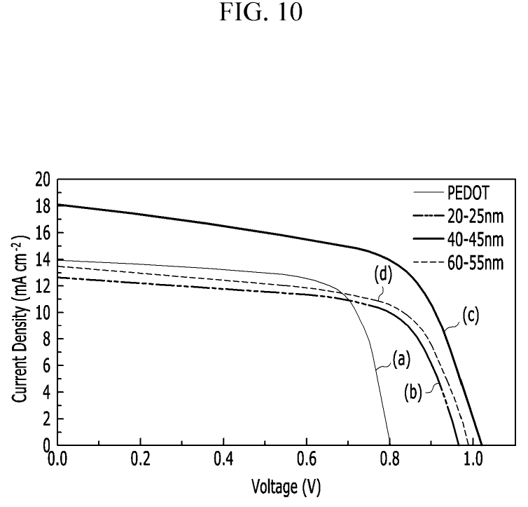

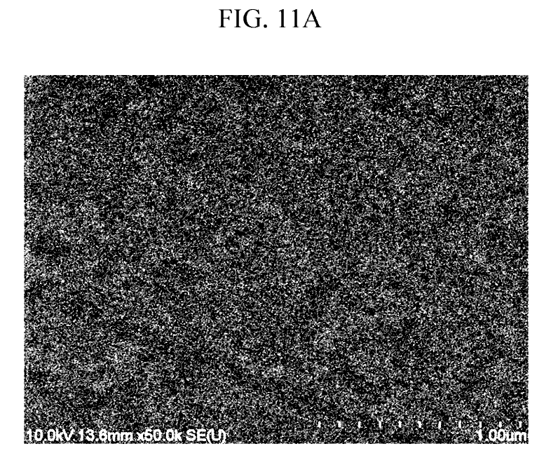

In addition, FIGS. 6 to 9 are graphs showing the results of Table 1. FIG. 6 is a graph comparing voltage characteristics of a solar cell respectively using a conventional hole transport layer and a hole transport layer according to examples, FIG. 7 is a graph comparing their current density characteristics, FIG. 8 is a graph comparing their fill factor characteristics, and FIG. 9 is a graph comparing their power conversion efficiency characteristics. In addition, FIG. 10 is a graph comparing current density characteristics with respect to a voltage of the conventional hole transport layer and the hole transport layer according to examples.

Referring to Table 1 and FIGS. 6 to 10, the solar cell including the hole transport layer according to Example 1 shows equivalent or excellent electrical characteristics compared with those of the solar cell having the hole transport layer including PEDOT:PSS.

For example, when the hole transport layer includes nickel oxide nanoparticles and has a thickness of about 40 to about 45 nm, current density is 17.34 mA/cm² and power conversion efficiency is 10.2%, and accordingly, excellent performance is obtained.

TABLE 1

| Hole transport layer | Voc (V) | Jsc (mA/cm²) | FF | PCE (%) |
|---|---|---|---|---|
| PEDOT:PSS | 0.80 | 13.88 | 0.71 | 7.9 |
| NiO NP | 0.93 | 11.09 | 0.66 | 6.7 |
| 25-30 nm | | | | |
| NiO NP | 1.00 | 17.34 | 0.60 | 10.2 |
| 40-45 nm | | | | |
| NiO NP | 0.99 | 13.42 | 0.61 | 7.7 |
| 60-65 nm | | | | |

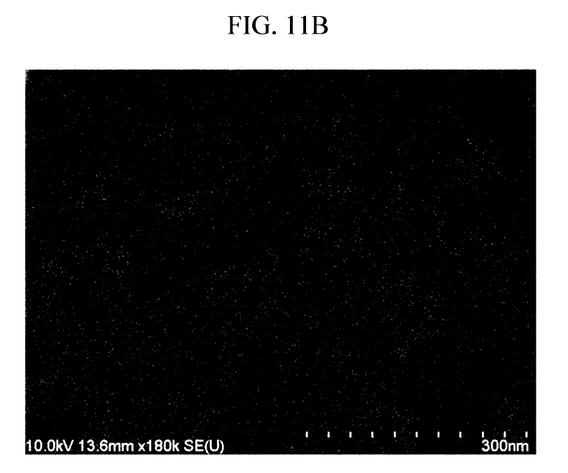

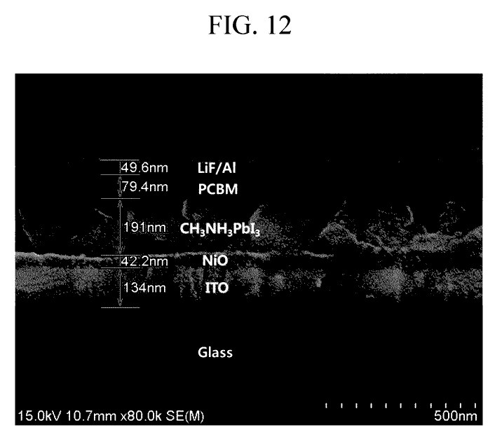

On the other hand, FIG. 11A is a low magnification SEM image showing the surface of the thin film according to Example 2, and FIG. 11B is a high magnification SEM image showing the surface of the thin film according to Example 2. FIG. 12 is a SEM image showing the cross-section of a solar cell including the thin film according to Example 2 as a hole transport layer.

A solar cell 100 shown in FIG. 12 had a structure in which a substrate 110 including glass, a first electrode 120 including ITO, a hole transport layer 130 of the thin film according to Example 1, an active layer 140 including CH₃NH₃PbI₃, an electron transport layer 150 including PCBM (phenyl-C₆₁-butyric acid methyl ester), and a second electrode including LiF and Al are sequentially stacked. In FIG. 5, the hole transport layer 130 has a thickness of 42.2 nm, but may have various thicknesses by controlling the concentration of the ink.

When a solar cell has a hole transport layer including PEDOT:PSS, a voltage (Voc), a current density (Jsc), a fill factor (FF), and power conversion efficiency (PCE) of the solar cell in each case in which the hole transport layer 130 according to Example 2 has a thickness of about 25 nm to about 30 nm, about 40 nm to about 45 nm, and about 60 nm to about 65 nm are shown in Table 2.

Referring to Table 2, the solar cell including the hole transport layer according to Example 2 shows equivalent or excellent electrical characteristics compared with the solar cell having the hole transport layer including PEDOT:PSS.

TABLE 2

| Hole transport layer | Voc (V) | Jsc (mA/cm²) | FF | PCE (%) |
|---|---|---|---|---|
| PEDOT:PSS | 0.80 | 13.88 | 0.71 | 7.9 |
| NiO NP | 0.91 | 11.26 | 0.60 | 6.1 |
| 25-30 nm | | | | |
| NiO NP | 0.94 | 13.38 | 0.62 | 7.8 |
| 40-45 nm | | | | |
| NiO NP | 0.91 | 10.04 | 0.57 | 5.2 |
| 60-65 nm | | | | |

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A method for manufacturing a thin film, comprising:
preparing an ink in which nickel oxide (NiO) nanoparticles are uniformly dispersed;
coating the ink on a base layer; and
curing the ink to form a thin film including nickel oxide nanoparticles,
wherein the preparing of the ink includes:
preparing a precursor solution including a nickel oxide nanoparticle precursor;
adding a reducing agent to the precursor solution to produce nickel oxide nanoparticles by reducing the nickel oxide nanoparticle precursor;
separating the nickel oxide nanoparticles from the precursor solution; and
uniformly dispersing the separated nickel oxide nanoparticles in an organic solvent to prepare the ink.

2. The method of claim 1, wherein the nickel oxide nanoparticle precursor is nickel(II) acetylacetonate (C₁₀H₁₄NiO₄).

3. The method of claim 2, wherein the solvent of the precursor solution is oleylamine (C₁₈H₃₇N).

4. The method of claim 1, wherein the reducing agent is borane-dimethylamine ((CH₃)₂NH.BH₃), borane-triethylamine ((C₂H₅)₃N.BH₃), or borane-trimethylamine ((CH₃)₃N.BH₃).

5. The method of claim 1, wherein in the separating of the nickel oxide nanoparticles, the nickel oxide nanoparticles are separated from the precursor solution through centrifugation.

6. The method of claim 1, wherein the organic solvent is tetradecane (C₁₄H₃₀).

7. The method of claim 1, wherein in the preparing of the ink, the nickel oxide nanoparticles are uniformly dispersed in an organic solvent through an ultrasonication treatment.

8. The method of claim 1, wherein in the forming of the thin film, the ink is heated at a temperature of about 200° C. to about 500° C. to cure the ink.

9. The method of claim 1, wherein in the forming of the thin film, a laser is irradiated to the ink to cure the ink.

10. The method of claim 1, wherein in the producing of the nickel oxide nanoparticles, the precursor solution is heated and stirred at a temperature of about 80° C. to about 200° C. for about 1 hour or more and then the reducing agent is added.

11. The method of claim 1, wherein between the separating of the nickel oxide nanoparticles and the preparing of the ink, the method further includes washing the nickel oxide nanoparticles with methanol, ethanol, or acetone.

12. A solar cell comprising
a first electrode, a hole transport layer, an active layer, an electron transport layer, and a second electrode that are sequentially stacked on a substrate,
wherein the hole transport layer is a thin film where nickel oxide nanoparticles are uniformly dispersed.

13. The solar cell of claim 12, wherein the solar cell further includes a hole injection layer between the first electrode and the hole transport layer, and the hole injection layer is a thin film where nickel oxide nanoparticles are uniformly dispersed.

14. The solar cell of claim 12, wherein a thickness of the hole transport layer is in a range of about 10 nm to about 100 nm.

15. The solar cell of claim 12, wherein the first electrode includes an ITO, the active layer includes CH₃NH₃PbI₃, the electron transport layer includes PCBM (phenyl-C₆₁-butyric acid methyl ester), and the second electrode includes LiF and Al.
